(19) United States
(12) Patent Application Publication
(10) Pub. No.: US 2008/0045013 A1
(43) Pub. Date: Feb. 21, 2008

(54) Iridium encased metal interconnects for integrated circuit applications

(76) Inventors: Adrien R. Lavoie, Beaverton, OR (US); John J. Plombon, Portland, OR (US); Juan E. Dominguez, Hillsboro, OR (US); Joseph H. Han, San Jose, CA (US); Harsono S. Simka, Saratoga, CA (US); Ting Zhong, Tigard, OR (US); Eric Dickey, Portland, OR (US); Bill Barrow, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/506,358

(22) Filed: Aug. 18, 2006

(51) Int. Cl. H01L 21/44

(52) U.S. Cl. 438/687

(57) ABSTRACT

An iridium encased copper interconnect comprises an iridium liner formed within a trench in a dielectric layer, wherein the iridium liner is formed directly on the dielectric layer, a copper interconnect formed on the iridium liner, and an iridium capping layer formed on the copper interconnect. The iridium encased copper interconnect may be fabricated by providing a semiconductor substrate in a reactor, wherein the semiconductor substrate includes a trench etched into a dielectric layer, pulsing trimethylaluminum into the reactor proximate to the semiconductor substrate, pulsing an iridium precursor into the reactor proximate to the semiconductor substrate, wherein the trimethylaluminum enables an iridium species to deposit directly on the dielectric layer, depositing a copper seed layer on the iridium species layer using an electroless deposition process, and depositing a bulk copper layer on the copper seed layer using an electroplating process.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The Ta or Ru adhesion layer is required because the subsequently deposited metals do not readily nucleate on the TaN barrier layer. This may be followed by a PVD sputter process to deposit a copper seed layer into the trench. An electroplating process is then used to fill the trench with copper metal to form the interconnect.

As device dimensions scale down, the aspect ratio of the trench becomes more aggressive as the trench becomes narrower. This gives rise to issues such as trench overhang during the copper seed deposition and plating processes, leading to pinched-off trench openings and inadequate electroplating gapfill. Additionally, as trenches decrease in size, the ratio of barrier metal to copper metal in the overall interconnect structure increases, thereby increasing the electrical line resistance and RC delay of the interconnect.

One approach to addressing these issues is to reduce the thickness of the TaN/Ta or TaN/Ru stack, which widens the available gap for subsequent metallization and increases the final copper volume fraction. Unfortunately, this is often limited by the non-conformal characteristic of PVD deposition techniques. Accordingly, alternative techniques for reducing the thickness of the barrier and adhesion layer are needed.

### BRIEF DESCRIPTION OF THE DRAWINGS

FIGS. 1A to 1E illustrate a conventional damascene process for forming metal interconnects.

FIG. 2 is a metal interconnect encased within an iridium shell formed in accordance with an implementation of the invention.

FIG. 3 is a method for forming an iridium liner using an iridium immobilization process in accordance with an implementation of the invention.

FIG. 4 illustrates an exemplary chelating group used to attach iridium metal to a dielectric layer.

FIG. 5 is a method for forming an iridium liner using a TMA-enhanced ALD process in accordance with an implementation of the invention.

FIG. 6 illustrates an iridium liner that is formed in accordance with implementations of the invention.

FIG. 7 is a method of forming a metal interconnect in accordance with an implementation of the invention.

FIGS. 8A through 8C illustrates various structures that are formed when the method of FIG. 7 is carried out.

FIG. 9 illustrates an ALD process for depositing an iridium capping layer in accordance with an implementation of the invention.

### DETAILED DESCRIPTION

Described herein are systems and methods of forming an iridium encased metal interconnect for use within the metallization layers of an integrated circuit die. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention include a metal interconnect, such as a copper interconnect, that is encased in an iridium shell. The copper interconnect may be used in integrated circuit applications, for instance, in back-end metallization layers that interconnect various devices formed on a semiconductor substrate. The iridium shell may be formed using an iridium liner and an iridium capping layer. The iridium liner may be disposed between the metal interconnect and an underlying dielectric layer and functions as both a barrier layer and an adhesion layer. The iridium capping layer may be formed atop the metal interconnect after the metal has been polished.

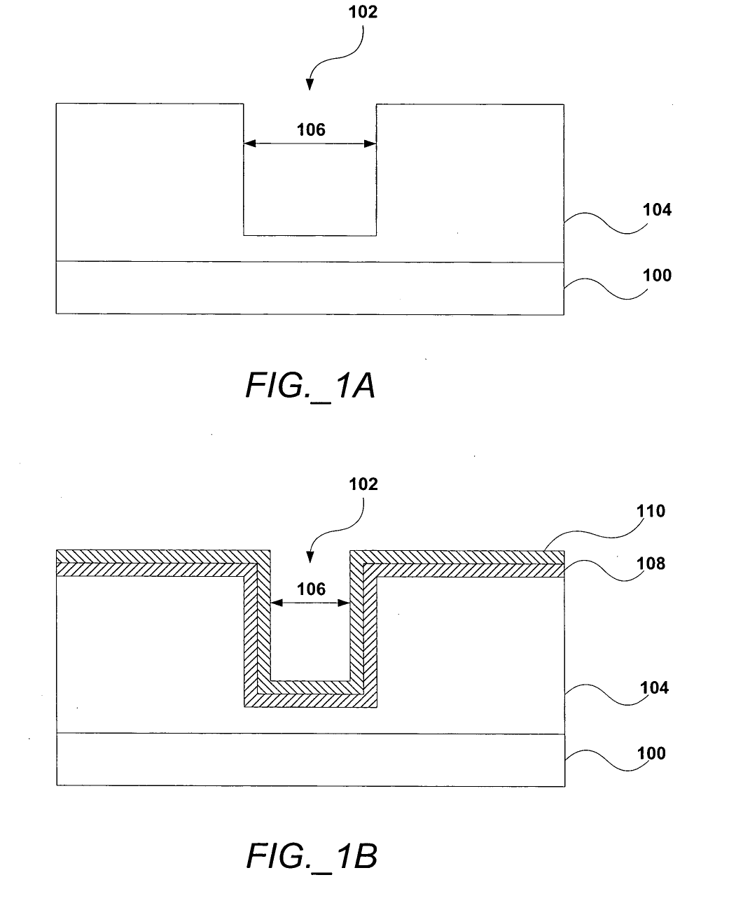

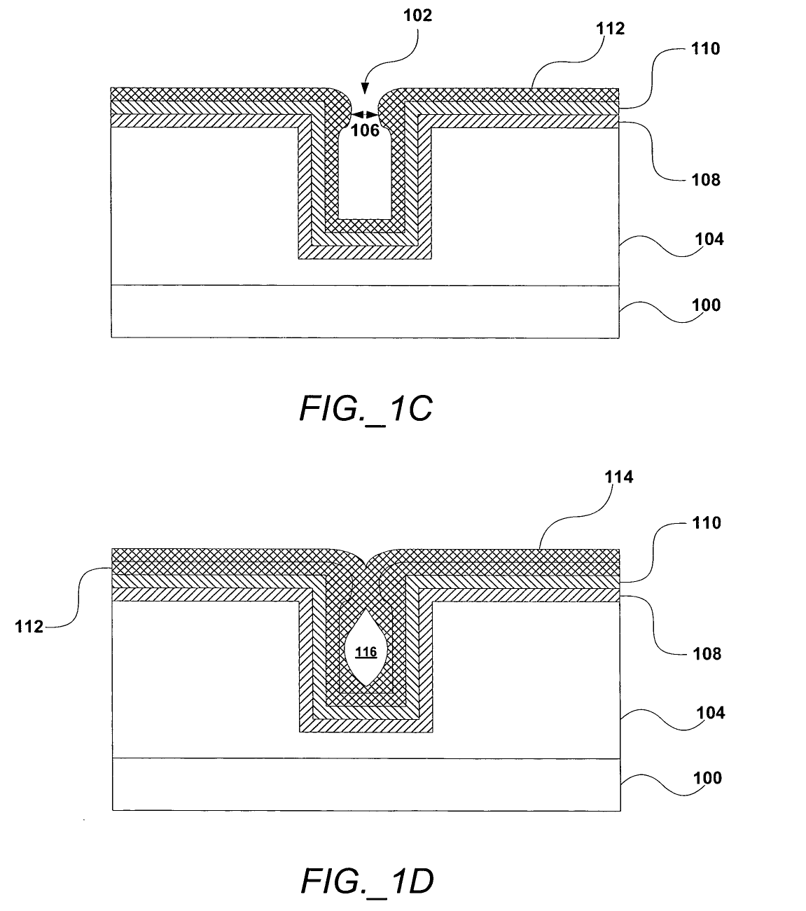

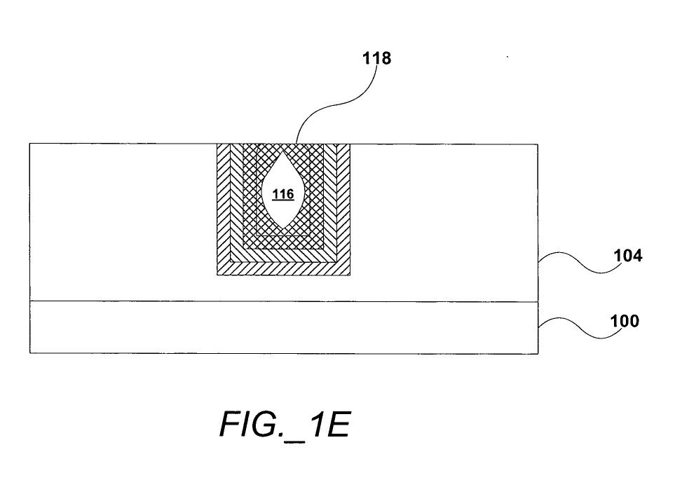

For reference, FIGS. 1A to 1E illustrate a conventional damascene process for fabricating copper interconnects on a semiconductor wafer. FIG. 1A illustrates a substrate 100, such as a semiconductor wafer, that includes a trench 102 that has been etched into a dielectric layer 104. The trench 102 includes a gap 106 through which metal may enter during metallization processes.

FIG. 1B illustrates the trench 102 after a conventional barrier layer 108 and a conventional adhesion layer 110 have been deposited. The barrier layer 108 prevents copper metal from diffusing into the dielectric layer 104. The adhesion layer 110 enables copper metal to become deposited onto the barrier layer 108. The barrier layer 108 is generally formed using a material such as tantalum nitride (TaN) and is deposited using a PVD process. The barrier layer 108 may be around 3 Angstroms (Å) to 10 nanometers (nm) thick, although it is generally around 5 nm thick. The adhesion layer 110 is generally formed using a metal such as tantalum (Ta) or ruthenium (Ru) and is also deposited using a PVD process. The adhesion layer 110 is generally around 5 nm to 10 nm thick.

After the adhesion layer 110 is formed, the conventional damascene process of FIG. 1 uses two independent deposition processes to fill the trench 102 with copper metal. The first deposition process is a PVD process that forms a non-conformal copper seed layer. The second deposition process is a plating process, such as an electroplating (EP) process or an electroless plating (EL) process, that deposits a bulk copper layer to fill the trench 102.

FIG. 1C illustrates the trench 102 after a conventional copper seed layer 112 has been deposited onto the adhesion layer 110 using a PVD process. The copper seed layer 112 enables or catalyzes a subsequent plating process to fill the interconnect with copper metal. FIG. 1D illustrates the trench 102 after an EP or EL copper deposition process has been carried out. Copper metal 114 enters the trench through the gap 106 where, due to the narrow width of the gap 106, issues such as trench overhang and pinching off of the trench opening may occur that lead to defects in the plating step. For instance, as shown in FIG. 1D, trench overhang may occur that pinches off the opening of the trench 102, creating a void 116 that will appear in the final interconnect structure.

FIG. 1E illustrates the trench 102 after a chemical mechanical polishing (CMP) process is used to planarize the deposited copper metal 114. The CMP results in the formation of a metal interconnect 118. As shown, the metal interconnect 118 includes the void 116 that was formed when the available gap 106 was too narrow and the resulting trench overhang pinched off the trench opening. Furthermore, a substantial portion of the metal interconnect 118 comprises Ta and/or Ru from the adhesion layer 110 and the barrier layer 108.

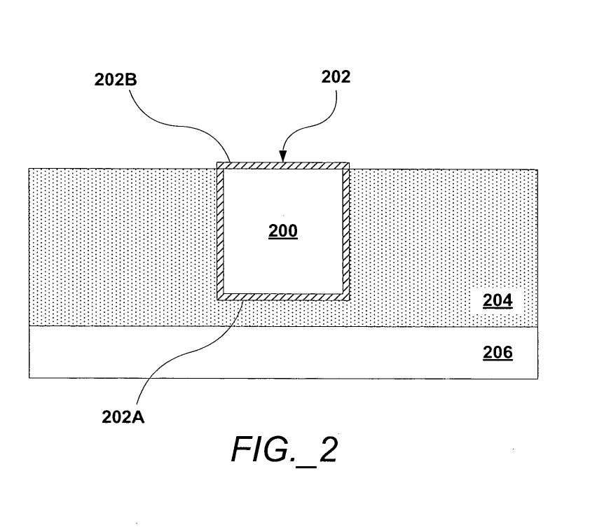

FIG. 2 illustrates a metal interconnect 200 formed within a trench of a dielectric layer 204 upon a substrate 206. The substrate 206 may be a portion of a semiconductor wafer. In accordance with an implementation of the invention, the metal interconnect 200 is encased within an iridium shell 202. A portion of the iridium shell 202, specifically an iridium liner 202A, functions as a barrier layer separating the metal interconnect 200 from the underlying dielectric layer 204 and preventing the metal from diffusing into the dielectric layer 204. The iridium liner 202A also functions as an adhesion layer that enables metal to be deposited within the trench to form the metal interconnect 200. Another portion of the iridium shell 202, specifically an iridium capping layer 202B, protects a top surface of the metal interconnect 200 from subsequently deposited layers.

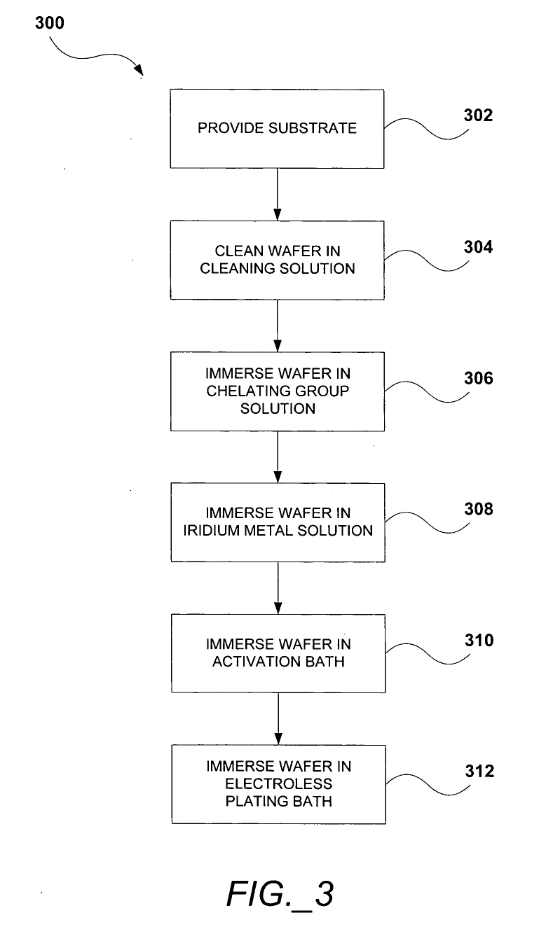

In various implementations of the invention, the iridium liner 202A may be formed using different processes such as an iridium-immobilization-process (IIP), an atomic layer deposition (ALD) process, or a chemical vapor deposition (CVD) process. FIG. 3 is a method 300 for forming the iridium liner 202A using an IIP process in accordance with one implementation of the invention.

The process 300 begins by providing a semiconductor substrate onto which a metal interconnect, such as a copper interconnect, may be formed (302). For instance, the semiconductor substrate may be a semiconductor wafer that includes a dielectric layer on its surface. The dielectric layer may include at least one trench in which the copper interconnect is to be formed. The dielectric layer may be formed from conventional materials used in dielectric layers, including but not limited to silicon dioxide (SiO₂) and carbon-doped oxide (CDO).

The substrate may be cleaned with a rinsing solution to remove impurities, contaminants, and/or oxides (304). The rinsing solution used may be an alkaline solution or a pure water rinse. The rinsing solutions may contain surfactants (e.g. polyoxyethylene derivatives), phosphates, and/or carbonates in alkaline media. These rinsing solutions tend to make the semiconductor substrate more hydrophilic and tend to remove loose particles due to the fluid motion on the wafer. Rinsing solutions typically used in a palladium-immobilization-process (PIP) may be used here, as will be known to those of ordinary skill in the art.

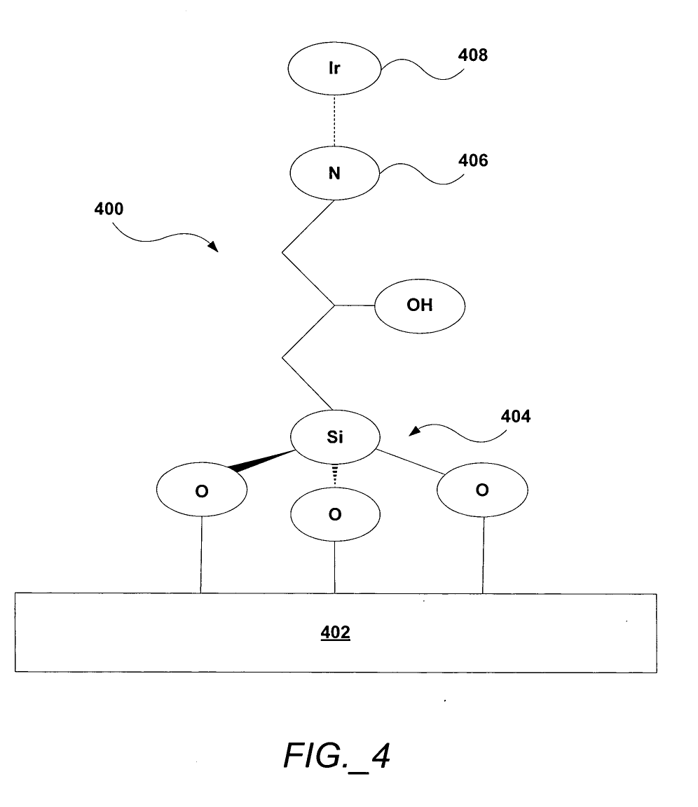

After the cleaning process, iridium metal may be deposited on the substrate and into the trench by way of a chelating group. Turning to FIG. 4, an exemplary chelating group 400 is shown attached to a substrate 402. The chelating group 400 may include silicon, for instance, the chelating group 400 may include a silyloxy group 404, which has the ability to bond strongly to many different types of materials, including but not limited to a dielectric layer. The chelating group 400 may also include a nitrogen group 406, which has the ability to bond to a metal catalyst such as iridium. The nitrogen group 406 may be provided by an amine or an azo group. For instance, in the implementation shown, the chelating group 400 may be an azo-silyloxy moiety and the nitrogen group 406 may be provided by the azo group. An iridium atom 408 may bond to the nitrogen 406 of the chelating group 400.

Returning to FIG. 3, in one implementation of the invention, the chelating group is deposited directly on the dielectric layer by immersing the substrate in a solution that contains the chelating group (306). When the substrate is immersed, the chelating group, including the azo-silyloxy moiety, attaches to the substrate with the silyloxy group bonded directly to the dielectric layer and leaving the azo group exposed. A layer of the chelating group is therefore deposited directly on the dielectric layer. This chelating group layer may or may not be continuous.

Next, the substrate may be immersed in a solution containing iridium metal (308). When the substrate is immersed, iridium metal in solution becomes bonded to the nitrogen in the exposed azo group. This results in the formation of an adsorbed layer of an iridium species over the chelating group. In some implementations of the invention, the source of the iridium may be IrF₃.H₂O, IrCl₃.H₂O, IrBr₃.H₂O, IrI₃.H₂O, Ir(CO)₂Cl₄, Ir(CO)₂Br₄, IrI(CO)₃, HIr(CO)₄, CpIr(CO)₂ (where Cp=cyclopentadienyl), pyrrolyl-Ir—(CO)₂—Cl, and ligand variations thereof including, but not limited to, allyl, vinyl, cyclohexadienyl, pentamethyl-Cp, (COD)IrCp (where COD=cyclooctadiene), Ir(COD)₂X₂ (where X=a halide), Ir(CO)X, CpIr(pyrrolyl)₃, hexadienyl-Ir(Cp), Ir(allyl)(pyrrolyl)₂, and IrH₅(PEt₃)₂ (where Et=ethyl).

In alternate implementations of the invention, the chelating group and the iridium metal may be applied using techniques other than immersion in two separate solutions. In some implementations, a wet chemical process may be used in which the substrate may be immersed in a solution containing both the chelating group and the iridium metal. In further implementations, CVD or ALD processes may be used in lieu of a wet chemical process. For instance, in one implementation, a wet chemical method may be used to attach the chelating group to the substrate, followed by an ALD or CVD process to attach the iridium metal to the chelating group.

After bonding to the substrate by way of the chelating group, the iridium metal is then immersed in an activation both that contains a reducing agent (310). As is well known in the art, the oxidized iridium metal is activated by being reduced in the activation bath (e.g., Ir³⁺ or Ir¹⁺ is reduced to Ir⁰). When activated, the metal center is electronically neutral and is in the metallic state. A layer of activated iridium metal is now covalently bonded to the chelating group, thereby forming a monolayer of iridium metal that is affixed to the surface of the dielectric layer. The underlying nitrogen containing group acts as an immobilizing structure that holds the iridium metal in place on the substrate.

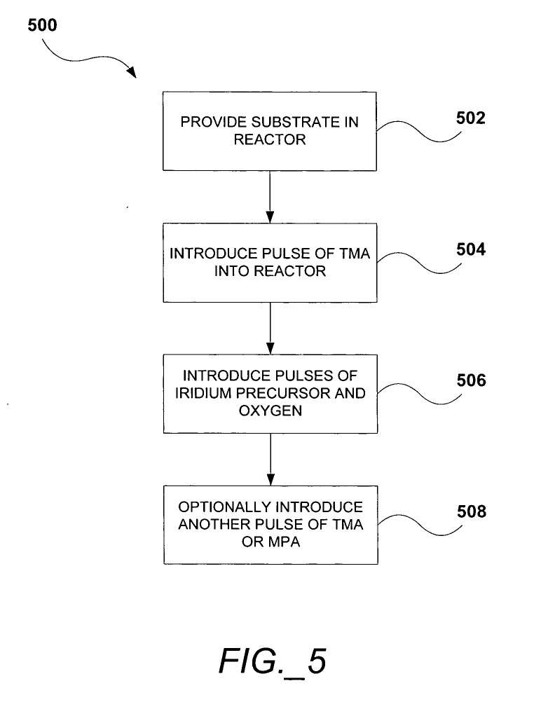

In another implementation of the invention, the iridium liner 202A may be formed using a novel ALD or CVD process that enables the iridium metal to be deposited directly on the dielectric layer without the need for a chelating group. FIG. 5 illustrates such a method 500, in this case an ALD process, in accordance with an implementation of the invention that utilizes one or more pre-pulses of an aluminum precursor such as trimethylaluminum (TMA) or methylpyrrolidinealane (MPA).

As before, the process 500 begins by providing a semiconductor substrate onto which a metal interconnect, such as a copper interconnect, may be formed (502). For instance, the semiconductor substrate may be a semiconductor wafer that includes a dielectric layer on its surface. The dielectric layer may include at least one trench in which the copper interconnect is to be formed. The dielectric layer may be formed from conventional materials used in dielectric layers, including but not limited to SiO₂ and CDO. The substrate is then placed in a reactor in preparation for an ALD or CVD process.

In accordance with an implementation of the invention, at least one pulse of TMA or MPA is introduced into the reactor (504). The presence of the TMA or MPA enables the deposition of iridium to occur directly upon the dielectric layer of the substrate. For example, a TMA pulse enables the subsequent deposition of iridium on CDO using a precursor such as Ir(acac)₃ at any temperature. A TMA pulse also enables the deposition of iridium on CDO using a precursor such as (MeCp)Ir(COD) at temperatures below 275° C. due to the much lower stability of the (MeCp)Ir(COD) precursor with temperature.

The following are process parameters that may be used for a TMA pulse in accordance with various implementations of the invention. The number of TMA pulses may range from one to ten pulses, with each pulse having a duration of between one and five seconds. Between each TMA pulse may be a one second to five second purge. The reactor pressure may be around 0.1 Torr to 0.5 Torr during the deposition. The TMA is pulsed into the reactor from a TMA source, which may be kept at a static pressure of around 3 Torr to 7 Torr when in a closed system. The TMA source is kept near room temperature (e.g., 20° C. to 25° C.) while the substrate temperature may vary between around 150° C. and 400° C. It should be noted that the scope of the invention includes any possible set of process parameters that may be used to carry out the implementations of the invention described herein.

The TMA or MPA pulse is followed by one or more pulses of iridium precursor and oxygen (506). In some implementations, the iridium precursor may be Ir(acac)₃ where acac=acetylacetonato. In other implementations, alternate iridium precursors may be used, including but not limited to Ir₄(CO)₁₂, IrH₃(PPh₃)₂, Ir(acac)₃, (MeCp)Ir(COD) where Cp=cyclopentadienyl and COD=cyclooctadiene, and IrCl(CO)(PPh₃)₂. The iridium precursor causes an iridium liner to be deposited on the dielectric layer and within the trench. Multiple pulses of iridium may be used to bring the iridium liner to a desired thickness.

Conventional process parameters may be used for the iridium pulse. For instance, in implementations of the invention, the process parameters for the iridium pulse include, but are not limited to, an iridium precursor discharge pulse duration of between around 1 second and 5 seconds. Before discharge, the gas line pressure may be set to around 0 to 5 psi, the orifice may be between 0.1 mm and 1.0 mm in diameter, and the charge pulse may be between 1 second and 5 seconds. The equilibration time with the valves closed may be 1 second to 5 seconds and the discharge pulse may be 1 second to 5 seconds. The reactor pressure may be between around 0.1 Torr and 0.5 Torr, the iridium precursor temperature may be between around 80° C. and 200° C., the substrate temperature may be between around 150° C. and 400° C., and an RF energy source may be applied at a power that ranges from 5 W to 40 W and at a frequency of 13.56 MHz, 27 MHz, or 60 MHz. It should be noted that the scope of the invention includes any possible set of process parameters that may be used to carry out the implementations of the invention described herein. Furthermore, the precursor and co-reactant (e.g., oxygen) can be flown or pulsed simultaneously to accomplish a CVD-type growth.

Optionally, in an alternate implementation of the invention, one or more additional pulses of TMA or MPA may be introduced into the reactor after the iridium liner has been formed (508). This additional TMA or MPA provides aluminum metal that may be used to dope a subsequently deposited copper metal layer. For instance, after the additional TMA or MPA is pulsed, an electroplating process may be used to deposit a bulk copper layer atop the iridium layer and the additional aluminum. An annealing process may follow that causes the aluminum to diffuse into the copper metal, thereby improving the electromigration properties of the copper interconnect. Typical annealing may be between 80° C. and 400° C. in an inert atmosphere for around 10 minutes to around 60 minutes.

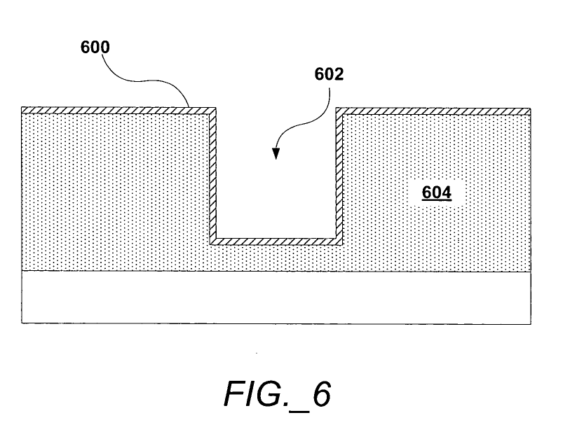

FIG. 6 illustrates an iridium liner 600 that is conformally formed within a trench 602 on a dielectric layer 604. The iridium liner 600 may be formed using either the IIP process of FIG. 3 or the TMA/MPA-enhanced ALD process of FIG. 5. The dielectric layer may be formed using any conventional dielectric material used in semiconductor processes, including but not limited to SiO₂ and CDO.

The iridium liner 600 functions as both a barrier to copper diffusion and as an adhesion layer that enables the direct plating of copper metal using one or a combination of an electroless plating process and an electroplating process. The iridium liner 600 therefore eliminates the need for the TaN/Ta stack or TaN/Ru stack used in conventional metal interconnects. In some implementations, the iridium liner 600 may further be used as a seed layer for the subsequent copper deposition, thereby eliminating the need for a copper seed layer.

The iridium liner 600 provides a thinner barrier and adhesion layer that widens the trench gap available for metallization, thereby enabling improved copper gapfill in narrower trenches with aggressive aspect ratios. In addition, due to the thinness of the iridium liner 600, the ratio of barrier metal-to-copper metal in the overall interconnect structure decreases (i.e., the copper line volume increases), which decreases the electrical line resistance and RC delay of the interconnect.

It will also be appreciated by those of skill in the art that the use of the TMA/MPA-enhanced ALD process to form the iridium liner replaces the conventional three step PVD process flow (i.e., PVD TaN deposition +PVD Ta deposition +PVD copper seed deposition) with a single ALD process. Therefore, when compared to the prior art, implementations of the invention reduces the number of process steps required, reduces the amount of wafer handling that occurs, reduces the number of process tools needed, and reduces the overall throughput time.

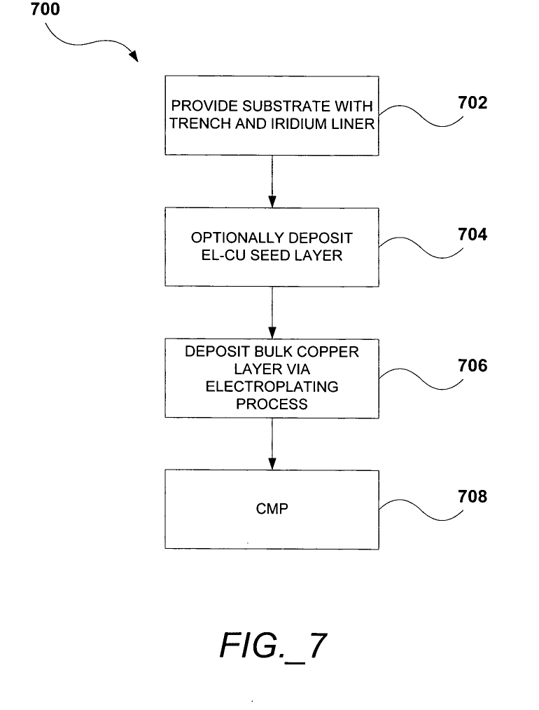

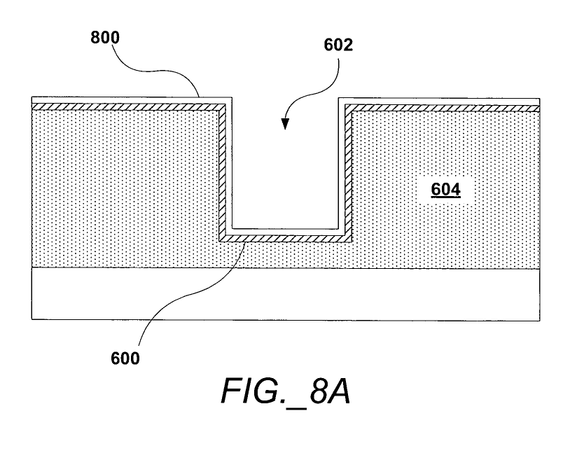

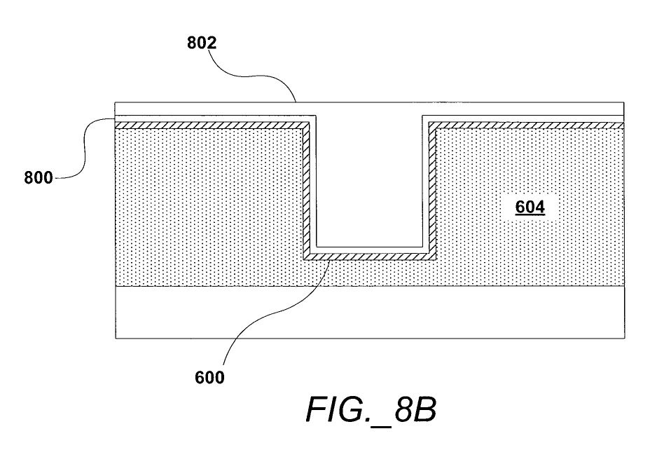

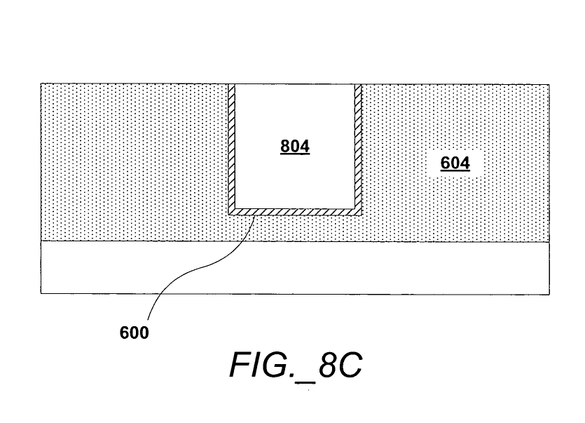

FIG. 7 is a method 700 of forming a metal interconnect in accordance with an implementation of the invention. FIGS. 6 and 8A through 8C illustrates various structures that are formed when the method 700 is carried out.

First, a substrate is provided that includes a dielectric layer having a trench and an iridium liner formed within at least the trench (702). The iridium liner may be formed using either the IIP process of FIG. 3 or the TMA/MPA-enhanced ALD process of FIG. 5. FIG. 6 illustrates such an iridium liner 600 that is conformally formed within a trench 602 on a dielectric layer 604.

Next, in some implementations of the invention, an optional electroless copper (EL-Cu) enhancement of the iridium liner may be carried out (704). The substrate with the iridium liner may be immersed into an electroless copper bath where an electroless deposition process is carried out to deposit a copper seed layer over the iridium liner, thereby forming an EL-Cu enhanced iridium liner. The iridium metal serves as a nucleation site for the electroless deposition to occur. The plating bath may contain a copper salt (e.g., copper sulfate), a complexing agent, a reducing agent, and a surfactant. The electroless deposition process may take place at a basic pH level (e.g., a pH level between pH 10 and pH 14) and at a temperature between around 50° C. and 100° C. The substrate may be immersed in the electroless plating bath for the time required to achieve the desired thickness, for example, a time period between 10 seconds and 120 seconds. In implementations, the thin copper seed layer may range from 5 Å to 100 Å. The copper seed layer enables or catalyzes a subsequent electroplating process to fill the interconnect with void-free copper metal.

FIG. 8A illustrates a copper seed layer 800 that has been deposited over the iridium liner 600. As shown, the electroless deposition results in a conformal layer of copper metal being formed over the iridium liner 600.

Following the optional deposition of the copper seed layer, an electroplating process is carried out to deposit a bulk copper layer over the EL-Cu enhanced iridium liner (706). The bulk copper layer fills the trench with copper to form the metal interconnect. The copper metal enters the trench where, due to the relatively large width of the trench enabled by the thin iridium liner, issues such as trench overhang are reduced or eliminated. The use of the optional EL-Cu enhances the noble metal layer catalytic properties for the electroplating process and substantially reduces or eliminates the formation of voids in the bulk copper layer within the trench.

FIG. 8B illustrates a bulk copper layer 802 that has been deposited onto the copper seed layer 800 using an electroplating process. As shown, the bulk copper layer 802 fills the trench 602 without voids.

Finally, a chemical mechanical polishing (CMP) process may be used to planarize the deposited copper metal and finalize the copper interconnect structure (708). FIG. 8C illustrates the formation of a copper interconnect 804 after the CMP process is used to planarize the deposited bulk copper layer 802, as well as portions of the iridium liner 600 and the copper seed layer 800.

In an implementation of the invention, an iridium capping layer may be deposited atop the copper interconnect, thereby forming a copper interconnect that is fully enclosed within an iridium shell. This structure was described above in FIG. 2, which shows the metal interconnect 200 encased within the iridium shell 202. The iridium shell 202 is shown as consisting of the iridium liner 202A and the iridium capping layer 202B.

In accordance with one implementation of the invention, to form the iridium capping layer, selective iridium deposition may be used on the bulk copper layer after the CMP process has completed. The presence of an iridium shell provides relatively strong protection for the copper interconnect due to the high oxidation resistance of the iridium metal. Iridium may also be used as an etch stop or, if modified chemically, as a non-reflective layer.

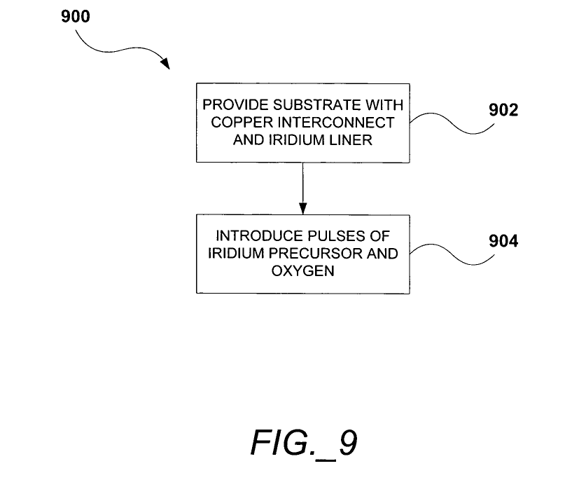

In implementations of the invention, the selective iridium deposition may be carried out using an ALD process. FIG. 9 illustrates one such ALD process 900 for depositing an iridium capping layer in accordance with an implementation of the invention. The process 900 begins by providing a semiconductor substrate that includes a metal interconnect, such as a copper interconnect formed on an iridium liner (902). This structure has been described above in FIG. 8C. The substrate is then placed in a reactor in preparation for an ALD process.

In accordance with an implementation of the invention, the ALD process is then carried out using an iridium precursor and O₂ or a reducing agent such as H₂ to minimize potential copper layer oxidation (904). In one implementation, the iridium precursor may be (MeCp)Ir(COD). In alternate implementations, the iridium precursor may be Ir₄(CO)₁₂, IrH₃(PPh₃)₂, Ir(acac)₃, or IrCl(CO)(PPh₃)₂.

One or more pulses of each precursor may be introduced into the reactor. Process parameters that may be used for the iridium capping layer ALD deposition when (MeCp)Ir(COD) is used as the precursor include, but are not limited to, a (MeCp)Ir(COD) pulse duration of between around 1 second and 5 seconds, a reactor pressure between around 0.1 Torr and 0.5 Torr, a (MeCp)Ir(COD) temperature between around 130° C. and 140° C., a substrate temperature between around 230° C. and 250° C., and an RF energy source applied at a power that ranges from 10 W to 30 W and at a frequency of 13.56 MHz, 27 MHz, or 60 MHz. It should be noted that the scope of the invention includes any possible set of process parameters that may be used to carry out the implementations of the invention described herein.

The ALD process may continue until the iridium capping layer has reached a desired thickness. FIG. 2 illustrates the end result of the deposition of the iridium capping layer. As described above, the result is a copper interconnect 200 encased within an iridium shell 202.

Implementations of the invention therefore enable a metal interconnect to be formed within an iridium shell. In addition, implementations of the invention enable the iridium-encased interconnect to be formed directly on a dielectric layer without the need for a conventional barrier and adhesion layer (e.g., a TaN/Ta stack). Elimination of the TaN/Ta stack widens the gap available for metallization, thereby allowing trenches with more aggressive aspect ratios to be filled with void-free metal using known plating processes. Furthermore, replacing the conventional TaN/Ta stack with a thin iridium liner increases the copper line volume, thereby reducing electrical resistance within the interconnect.

The above description of illustrated implementations of the invention, including what is described in the Abstract is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a semiconductor substrate that includes a trench etched into a dielectric layer;
cleaning the semiconductor substrate with a rinsing solution;
depositing a chelating group layer directly on the dielectric layer;
depositing an iridium species layer directly on the chelating group layer;
activating the iridium species layer;
depositing a copper seed layer on the iridium species layer using an electroless deposition process; and
depositing a bulk copper layer on the copper seed layer using an electroplating process.

2. The method of claim 1, wherein the cleaning of the semiconductor substrate comprises cleaning the semiconductor substrate with an alkaline solution or water.

3. The method of claim 2, wherein the alkaline solution further comprises at least one of a surfactant, a phosphate, or a carbonate.

4. The method of claim 1, wherein the depositing of the chelating group comprises immersing the semiconductor substrate in a solution that contains the chelating group.

5. The method of claim 1, wherein the chelating group comprises an azo-silyloxy moiety.

6. The method of claim 4, wherein the depositing of the iridium species layer comprises immersing the semiconductor substrate in a solution that contains the iridium species.

7. The method of claim 6, wherein the solution that contains the iridium species comprises a solution that contains at least one of IrF₃.H₂O, IrCl₃.H₂O, IrBr₃.H₂O, IrI₃.H₂O, Ir(CO)₂Cl₄, Ir(CO)₂Br₄, IrI(CO)₃, HIr(CO)₄, CpIr(CO)₂, pyrrolyl-Ir—(CO)₂—Cl, and ligand variations thereof including allyl, vinyl, cyclohexadienyl, pentamethyl-Cp, (MeCp)Ir(COD), Ir(COD)₂X₂, Ir(CO)X, CpIr(pyrrolyl)₃, hexadienyl-Ir(Cp), Ir(allyl)(pyrrolyl)₂, and IrH₅(PEt₃)₂.

8. The method of claim 1, wherein the depositing of the chelating group and the depositing of the iridium species layer comprises immersing the semiconductor substrate in a solution that contains both the chelating group and the iridium species.

9. The method of claim 4, wherein the depositing of the iridium species layer comprises using an ALD or CVD process to deposit the iridium species on the chelating group layer.

10. The method of claim 1, wherein the activating of the iridium species layer comprises immersing the semiconductor substrate in a solution that contains a reducing agent.

11. A method comprising:
providing a semiconductor substrate in a reactor, wherein the semiconductor substrate includes a trench etched into a dielectric layer;
pulsing an aluminum precursor into the reactor proximate to the semiconductor substrate;
pulsing an iridium precursor into the reactor proximate to the semiconductor substrate, wherein the aluminum precursor enables an iridium species to deposit directly on the dielectric layer;
moving the semiconductor substrate into an electroless plating bath;
depositing a copper seed layer on the iridium species layer using an electroless deposition process;
moving the semiconductor substrate into an electroplating bath; and
depositing a bulk copper layer on the copper seed layer using an electroplating process.

12. The method of claim 11, wherein the aluminum precursor comprises trimethylaluminum.

13. The method of claim 11, wherein the aluminum precursor comprises methylpyrrolidinealane.

14. The method of claim 11, wherein the iridium precursor comprises at least one of Ir(acac)₃, Ir(MeCp(COD)), Ir₄(CO)₁₂, IrH₃(PPh₃)₂, and IrCl(CO)(PPh₃)₂.

15. The method of claim 12, wherein the pulsing of the trimethylaluminum into the reactor comprises:
establishing a reactor pressure around 0.1 Torr to 0.5 Torr;
establishing a semiconductor substrate temperature around 150° C. to 400° C.;
establishing a trimethylaluminum source pressure around 3 Torr to 7 Torr and a trimethylaluminum source temperature around 20° C. to 25° C.;
introducing 1 to 10 pulses of trimethylaluminum into the reactor from the trimethylaluminum source, wherein a time duration for each pulse is around 1 to 5 seconds; and
purging the reactor between each pulse of trimethylaluminum, wherein a time duration for each purge is around 1 to 5 seconds.

16. The method of claim 15, wherein the pulsing of the iridium precursor into the reactor comprises:
maintaining the reactor pressure around 0.1 Torr to 0.5 Torr;
maintaining the semiconductor substrate temperature around 150° C. to 400° C.;
establishing a gas line pressure around 0 to 5 psi;
establishing an iridium precursor temperature around 80° C. to 200° C.
introducing at least one pulse of the iridium precursor into the reactor, wherein a time duration for each pulse is around 1 to 5 seconds;
introducing at least one pulse of a co-reactant into the reactor, wherein a time duration for each pulse is around 1 to 5 seconds; and
applying an RF energy source at a power that ranges from 5 W to 40 W at a frequency of 13.56 MHz, 27 MHz, or 60 MHz.

17. The method of claim 11, further comprising pulsing trimethylaluminum or methylpyrrolidinealane into the reactor proximate to the semiconductor substrate after the iridium deposition but prior to the copper seed layer deposition.

18. The method of claim 17, further comprising annealing the semiconductor substrate at a temperature between 80° C. and 400° C. in an inert atmosphere for a time duration around 10 minutes to 60 minutes, thereby causing the additional trimethylaluminum or methylpyrrolidinealane to diffuse into the copper layer.

19. The method of claim 16, wherein the co-reactant comprises oxygen.

20. The method of claim 1, further comprising:
planarizing the bulk copper layer using a CMP process; and
depositing an iridium capping layer on the planarized bulk copper layer using an ALD process.

21. The method of claim 20, wherein the depositing of the iridium capping layer comprises:
providing the semiconductor substrate in a reactor;
establishing a reactor pressure around 0.1 Torr to 0.5 Torr;
establishing a semiconductor substrate temperature around 230° C. to 250° C.;
establishing an iridium precursor temperature around 130° C. to 140° C.;
introducing at least one pulse of the iridium precursor into the reactor, wherein a time duration for each pulse is 1 to 5 seconds; and
applying an RF energy source at a power that ranges from 10 W to 30 W at a frequency of 13.56 MHz, 27 MHz or 60 MHz.

22. The method of claim 21, wherein the iridium precursor comprises at least one of (MeCp)Ir(COD), Ir₄(CO)₁₂, IrH₃(PPh₃)₂, Ir(acac)₃, and IrCl(CO)(PPh₃)₂.

23. The method of claim 11, further comprising:
planarizing the bulk copper layer using a CMP process; and
depositing an iridium capping layer on the planarized bulk copper layer using an ALD process.

24. The method of claim 23, wherein the depositing of the iridium capping layer comprises:
providing the semiconductor substrate in a reactor;
establishing a reactor pressure around 0.1 Torr to 0.5 Torr;
establishing a semiconductor substrate temperature around 230° C. to 250° C.;
establishing an iridium precursor temperature around 130° C. to 140° C.;
introducing at least one pulse of the iridium precursor into the reactor, wherein a time duration for each pulse is 1 to 5 seconds; and
applying an RF energy source at a power that ranges from 10 W to 30 W at a frequency of 13.56 MHz, 27 MHz, or 60 MHz.

25. The method of claim 24, wherein the iridium precursor comprises at least one of (MeCp)Ir(COD), Ir₄(CO)₁₂, IrH₃(PPh₃)₂, Ir(acac)₃, and IrCl(CO)(PPh₃)₂.

26. An apparatus comprising:
an iridium liner formed within a trench in a dielectric layer, wherein the iridium liner is formed directly on the dielectric layer;
a metal interconnect formed on the iridium liner; and
an iridium capping layer formed on the metal interconnect.

27. The apparatus of claim 26, wherein the metal interconnect comprises copper metal.

28. The apparatus of claim 26, wherein the dielectric layer comprises silicon dioxide or carbon doped oxide.

29. The apparatus of claim 26, wherein a chelating group is present at the interface between the iridium liner and the dielectric layer.

30. The apparatus of claim 26, wherein trimethylaluminum or methylpyrrolidinealane is present at the interface between the iridium liner and the dielectric layer.

31. The apparatus of claim 27, wherein the copper metal is doped with aluminum proximate to the interface between the copper interconnect and the iridium liner.

32. The apparatus of claim 29, wherein the chelating group comprises an azo-silyloxy moiety.
